(19) United States
(12) Patent Application Publication
(10) Pub. No.: US 2016/0365438 A1
(43) Pub. Date: Dec. 15, 2016

(54) METHOD OF MANUFACTURING NITRIDE SEMICONDUCTOR DEVICE AND NITRIDE SEMICONDUCTOR DEVICE

(71) Applicant: FUJI ELECTRIC CO., LTD., Kanagawa (JP)

(72) Inventors: Shinya TAKASHIMA, Hachioji-city (JP); Ryo TANAKA, Santa Barbara-city, CA (US); Katsunori UENO, Matsumoto-city (JP); Masaharu EDO, Tokorozawa-city (JP)

(21) Appl. No.: 15/060,597

(22) Filed: Mar. 3, 2016

(30) Foreign Application Priority Data
Jun. 15, 2015 (JP) 2015-120223

(51) Int. Cl. H01L 29/78; H01L 21/306; H01L 29/66; H01L 29/207; H01L 29/10; H01L 21/324; H01L 29/20

(52) U.S. Cl. CPC H01L 29/7802; H01L 21/324; H01L 21/30625; H01L 29/2003; H01L 29/207; H01L 29/1095; H01L 29/66522; H01L 29/66712

(57) ABSTRACT

The region having the surface roughness has nitrogen vacancies, which serve as compensating donors for acceptors and therefore cannot achieve a sufficiently high p-type carrier concentration. In addition, the surface of the GaN-based material may be contaminated as a result of diffusion of impurities from the protective film or insufficient removal of the protective film. Such contamination may adversely affect the subsequent steps or the characteristics of completed devices.

A first aspect of the innovations herein provides a method of manufacturing a nitride semiconductor device, including thermally treating a nitride semiconductor layer or removing a film formed on a front surface of the nitride semiconductor layer, and polishing the front surface of the nitride semiconductor layer after the thermally treating or the removing.

The contents of the following Japanese patent application are incorporated herein by reference: NO. 2015-120223 filed on Jun. 15, 2015.

### BACKGROUND

1. Technical Field

The present invention relates to a method of manufacturing a nitride semiconductor device and a nitride semiconductor device.

2. Related Art

After subjected to ion implantation, a semiconductor substrate is thermally treated at a high temperature in a crystal recovery step and an impurity activation step. For example, when the semiconductor substrate is made of a gallium nitride (GaN)-based material, the semiconductor substrate is thermally treated at a temperature of 800° C. or higher. If the GaN-based semiconductor substrate is thermally treated at a temperature of 800° C. or higher, the GaN-based material is decomposed at the surface of the GaN-based material and nitrogen (N) atoms resultantly dissociate from the surface of the GaN-based material. In order to prevent the dissociation of the N atoms, a protective film (a cap layer) is provided on the GaN-based material in the thermal treatment steps (for example, see Japanese Patents Nos. 2540791 and 3244980.

The semiconductor substrate may be thermally treated at a temperature higher than 1100° C. in the impurity activation step and at approximately 1500° C. in the crystal recovery step. In these cases, the use of the protective film can not sufficiently prevent the dissociation of the nitrogen atoms from the surface of the GaN-based material. As a result, the surface of the GaN-based material becomes rough and uneven. The rough region of the surface has nitrogen vacancies, which serve as compensating donors for acceptors and therefore cannot achieve a sufficiently high p-type carrier concentration as designed. In addition, the surface of the GaN-based material may be contaminated as a result of diffusion of impurities from the protective film or insufficient removal of the protective film. Such contamination may adversely affect the subsequent steps or the characteristics of completed devices. It should be noted that, even if the thermal treatment steps are not performed, the formation and removal of the protective film may result in the rough surface of the GaN-based material. Furthermore, it is known to polish a deposited insulative film using CMP to externally expose an interface enforcement layer (see, for example, Japanese Patent No. 4044497).

However, the CMP step to externally expose the interface enforcement layer is not designed to compensate for the roughness of the surface of the GaN-based material. The objective of the present invention is to remove the rough region of the surface of the GaN-based material to achieve a flat surface.

### SUMMARY

A first aspect of the innovations herein may include a method of manufacturing a nitride semiconductor device, including thermally treating a nitride semiconductor layer or removing a film formed on a front surface of the nitride semiconductor layer, and polishing the front surface of the nitride semiconductor layer after the thermally treating or the removing.

A second aspect of the innovations herein may include a nitride semiconductor device including a nitride semiconductor layer, and an impurity region provided in the nitride semiconductor layer on a side of a front surface thereof. Here, maximum height roughness Rz of the front surface of the nitride semiconductor layer is less than 1 nm.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows a manufacturing flow 90 for manufacturing a nitride semiconductor device 100 according to a first embodiment.

FIG. 2 is a cross-sectional view showing a semiconductor substrate 10 on which the respective steps shown in FIG. 1 are to be performed.

FIG. 3 shows a doping step S10.

FIG. 4 shows a step S20 of forming a protective film 18.

FIG. 5 shows a thermal treatment step S30.

FIG. 6 shows a step S40 of removing the protective film 18.

FIG. 7 shows a step S50 of polishing a front surface 11.

FIG. 8 shows a step S60 of forming a front-surface structure 40 and a back-surface structure 50.

FIGS. 9A to 9E are AFM images showing the front surface 11 of the semiconductor substrate 10.

FIGS. 10A to 10E are three-dimensional views showing the unevenness of the front surface 11 of the semiconductor substrate 10.

FIGS. 11A to 11E are graphs showing the unevenness of the front surface 11 of the semiconductor substrate 10.

FIG. 12 shows a manufacturing flow 94 for manufacturing the nitride semiconductor device 100 according to a second embodiment.

FIG. 13 shows a step S55 of polishing the front surface 11.

FIG. 14 shows a manufacturing flow 98 for manufacturing a nitride semiconductor devices 110 according to a third embodiment.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

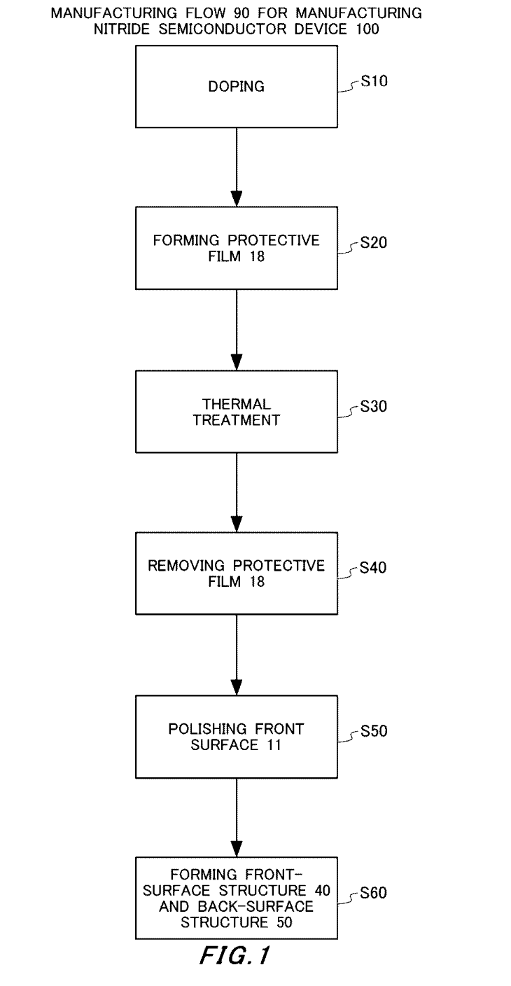

FIG. 1 shows a manufacturing flow 90 for manufacturing a nitride semiconductor device 100 according to a first embodiment. The manufacturing flow 90 includes a doping step (S10), a step of forming a protective film 18 (S20), a thermal treatment step (S30), a step of removing the protective film 18 (S40), a step of polishing a front surface 11 (S50), and a step of forming a front-surface structure 40 and a back-surface structure 50 (S60). According to the manufacturing flow 90 of the present exemplary embodiment, the steps S10, S20, S30, S40, S50 and S60 are performed in the stated order.

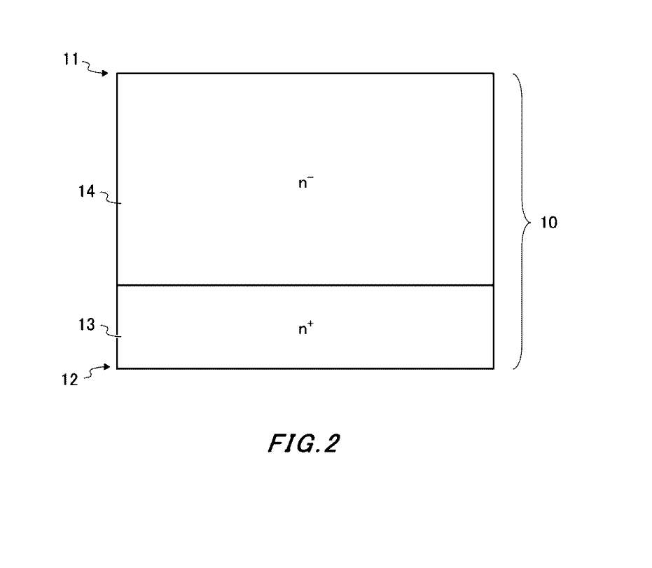

FIG. 2 is a cross-sectional view showing a semiconductor substrate 10 on which the respective steps shown in FIG. 1 are to be performed. Here, FIGS. 2 to 8 are cross-sectional views showing the semiconductor substrate 10. The semiconductor substrate 10 includes a high-concentration impurity layer 13 and a nitride semiconductor layer 14. In the present exemplary embodiment, the high-concentration impurity layer 13 is an n⁺-type GaN substrate. In the present exemplary embodiment, the nitride semiconductor layer 14 is an n⁻-type GaN layer that is epitaxially grown in contact with the high-concentration impurity layer 13. The nitride semiconductor layer 14 serves as a drift layer. In other examples, the nitride semiconductor layer 14 may be an n⁻-type InGaN layer containing indium (In), an n⁻-type AlGaN layer containing aluminum (Al), or an n⁻-type InAlGaN layer containing In and Al.

The nitride semiconductor layer 14 may have an n-type impurity concentration of approximately 1E16 cm⁻³ and a thickness of approximately 10 μm from the surface thereof on the side of a back surface 12 to the surface thereof on the side of the front surface 11. Here, the letter “E” means powers of 10. For example, E14 means 10 to the power of 14.

In the present specification, one of the surfaces of the nitride semiconductor layer 14 which faces away from the junction surface at which the nitride semiconductor layer 14 is connected to the high-concentration impurity layer 13 is referred to as the front surface 11. Additionally, in the present specification, one of the surfaces of the high-concentration impurity layer 13 which faces away from the junction surface at which the high-concentration impurity layer 13 is connected to the nitride semiconductor layer 14 is referred to as a back surface 12. Furthermore, in the present specification, one of two surfaces which is positioned closer to the front surface 11 is referred to as the surface on the side of the front surface 11, and one of two surfaces which is positioned closer to the back surface 12 is referred to as the surface on the side of the back surface 12. For example, the junction surface at which the high-concentration impurity layer 13 and the nitride semiconductor layer 14 are connected to each other is the surface of the high-concentration impurity layer 13 on the side of the front surface 11 and, at the same time, the surface of the nitride semiconductor layer 14 on the side of the back surface 12.

In the present specification, the letters “n” and “p” respectively mean that the electrons and holes serve as majority carriers, and the superscripts “+” and “−” added to the letters “n” and “p” have the following meanings. The superscript “+” indicates a higher carrier concentration when added than when not added, and the superscript “−” indicates a lower carrier concentration when added than when not added. In other examples, the letters “n” and “p” may have opposite meanings. For example, while the high-concentration impurity layer 13 and the nitride semiconductor layer 14 are both n-type in the present exemplary embodiment, the high-concentration impurity layer 13 and the nitride semiconductor layer 14 may be both p-type in other examples.

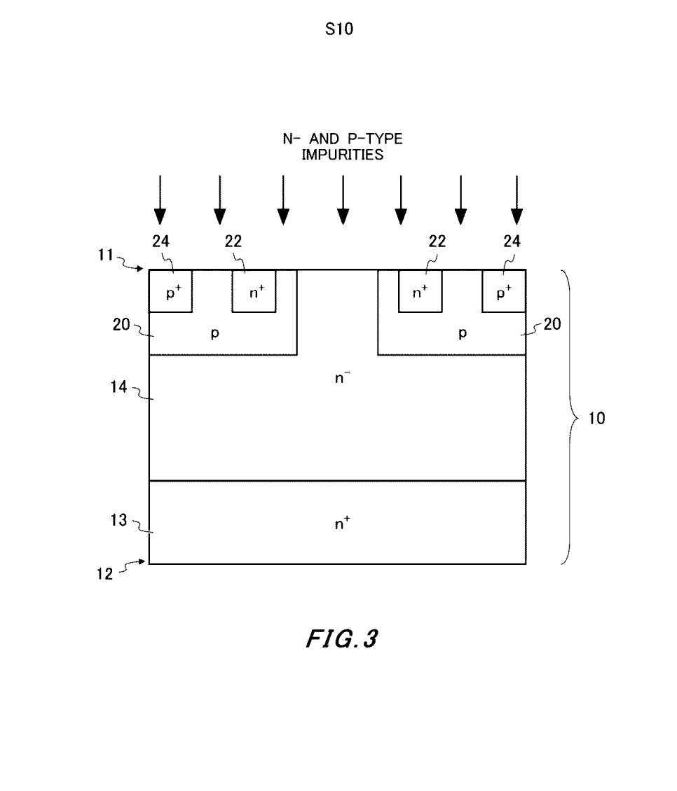

FIG. 3 shows the doping step S10. In the doping step S10 of the present exemplary embodiment, the front surface 11 of the nitride semiconductor layer 14 is doped with impurities. The doping step S10 of the present exemplary embodiment includes a p-type impurity doping step of forming a base region 20, which is a p-type impurity region, an n-type impurity doping step of forming a source region 22, which is an n⁺-type impurity region, and a p-type impurity doping step of forming a contact region 24, which is a p⁺-type impurity region.

The p-type impurities for the nitride semiconductor layer 14 may be at least one element selected from magnesium (Mg), beryllium (Be) and zinc (Zn). The n-type impurities for the nitride semiconductor layer 14 may be silicon (Si) or germanium (Ge). In the present exemplary embodiment, the base region 20 contains Mg of 1E17 cm⁻³ and the source region 22 contains Si of 1E20 cm⁻³. In the present exemplary embodiment, the contact region 24 contains Mg of 4E19 cm⁻³.

In the present exemplary embodiment, the base region 20 has a depth of 1 μm from the front surface 11 to the surface thereof on the side of the back surface 12. In the present exemplary embodiment, the source and contact regions 22 and 24 have a depth of 100 nm from the front surface 11 to the surface thereof on the side of the back surface 12. In the present exemplary embodiment, the source region 22 and the contact region 24 are separated away from each other. In a modification example of the present exemplary embodiment, an injection protective film having a thickness of approximately 50 nm may be provided in contact with the front surface 11 and the doping step S10 may be performed through the injection protective film.

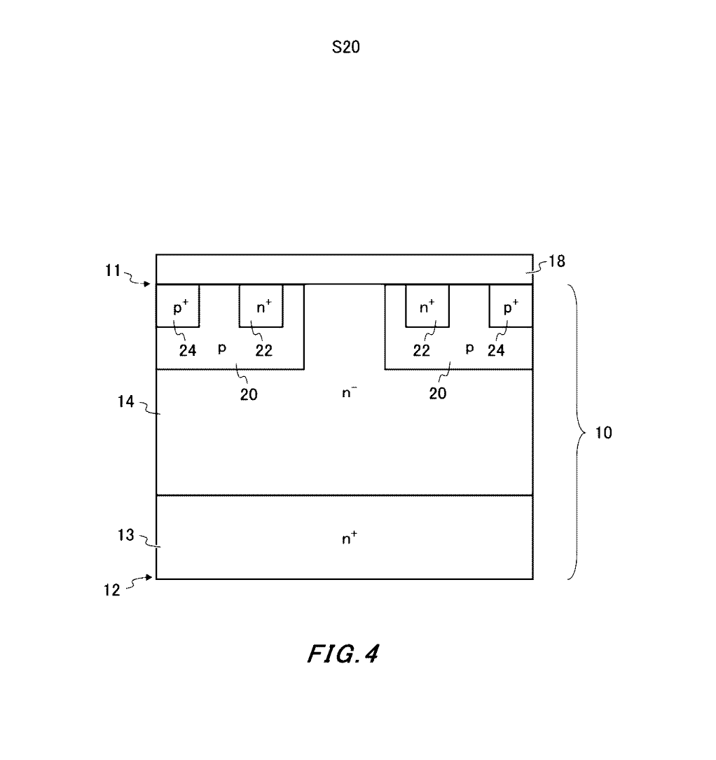

FIG. 4 shows the step S20 of forming the protective film 18. The protective film forming step S20 forms the protective film 18 on the front surface 11 of the nitride semiconductor layer 14. The protective film 18 may be one of an aluminum nitride (AlN) film, a silicon nitride (SiN,) film and a silicon oxide (SiO_{y}) film. Here, the letter “x” denotes the number of N atoms assigned to one Si atom and may take a value of no less than 1.2 and no more than 1.5. The letter “y” denotes the number of O atoms assigned to one Si atom and may take a value of no less than 1 and no more than 2.

The protective film 18 may be formed by sputtering or chemical vapor deposition (CVD), or, metal organic chemical vapor deposition (MOCVD). The use of MOCVD allows an epitaxial film to be formed. Note that CVD and MOCVD can accomplish reduced damage to the nitride semiconductor layer 14 when compared with the sputtering technique.

The protective film 18 may be formed in a manner suitable for its source material. The AlN film may be formed by sputtering or MOCVD, and the SiNₓ film and the SiOy film may be formed by sputtering or CVD. In the present exemplary embodiment, the protective film 18 is an AlN film, has a thickness of 200 nm, and is formed by sputtering.

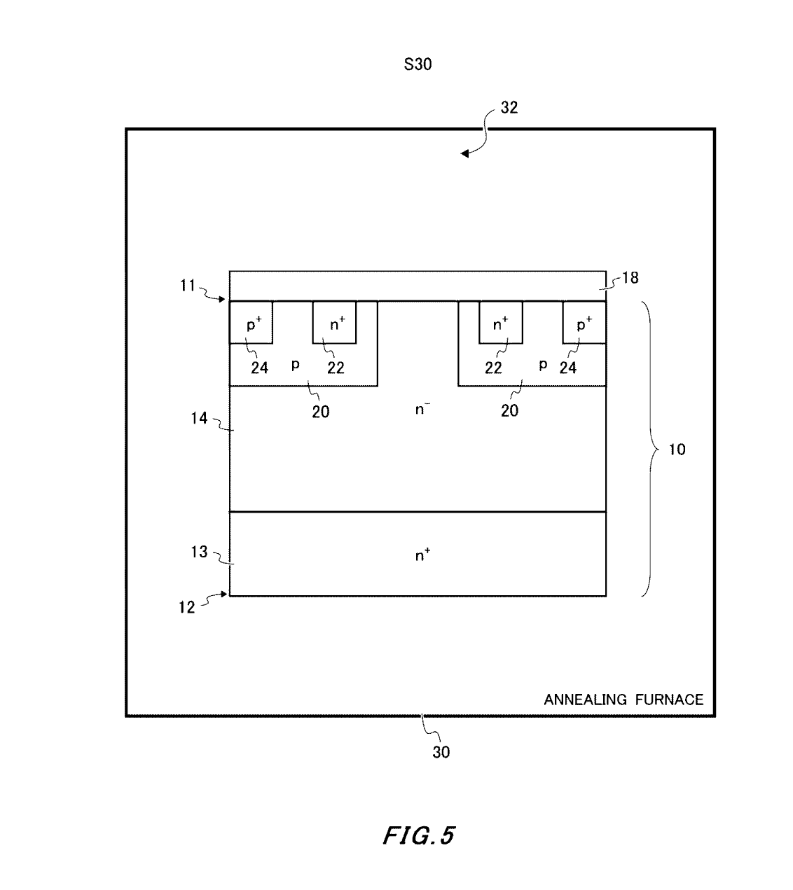

FIG. 5 shows the thermal treatment step S30. In the thermal treatment step S30, the nitride semiconductor layer 14 is thermally treated in an annealing furnace 30.

The thermal treatment step S30 may indicate a step of thermally treating the nitride semiconductor layer 14 at the highest temperature from among the steps included in the process of manufacturing the nitride semiconductor device 100. Here, the high-concentration impurity layer 13 may be heated to form the protective film 18, but it should be noted that this heating step is not included in the thermal treatment step S30. In the present exemplary embodiment, the nitride semiconductor layer 14 is thermally treated at 1300° C. for five minutes in the annealing furnace 30, which is filled with an atmosphere gas 32 of 1 atm that principally contains nitrogen gas. Note that, even if the protective film 18 is provided, nitrogen vacancies are inevitably formed in the front surface 11 of the nitride semiconductor layer 14 if thermal treatment is performed at a temperature exceeding 1100° C.

In the thermal treatment step S30, the annealing furnace 30 may be filled with the atmosphere gas 32 at a predetermined pressure that is determined according to the annealing temperature. For example, the annealing furnace 30 may be filled with a nitrogen gas (N₂) at a pressure of approximately 0.01 atm or higher for the temperature of 800° C., at a pressure of approximately 1 atm or higher for the temperature of 1000° C., and at a pressure of approximately 10 atm or higher for the temperature of 1100° C. The nitrogen gas (N₂) may be replaced with an ammonia gas (NH₃).

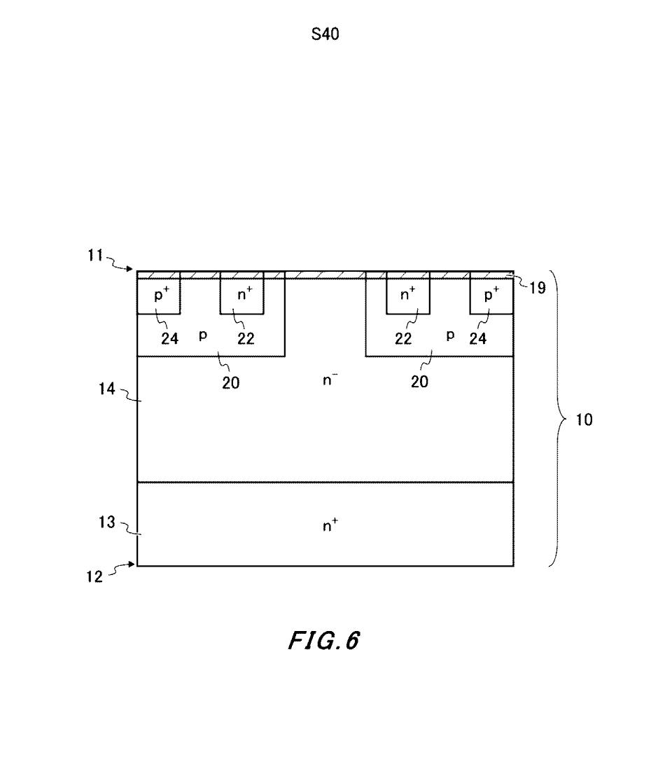

FIG. 6 shows a step S40 of removing the protective film 18. The protective film removal step S40 is designed to remove the protective film 18 using a single technique selected from among chemical mechanical polishing (CMP), dry etching and wet etching. In the present exemplary embodiment, the step S40 of removing the protective film 18 uses a different technique than the polishing step S50, which will be described later. In this manner, the best technique to remove the protective film 18 can be selected independently from the best technique to polish the front surface 11. This can reduce the time and cost required to perform the steps S 40 and S50.

In the present exemplary embodiment, the protective film removal step S40 removes the protective film 18 by means of wet etching using a potassium hydroxide aqueous solution (KOHaq). On the other hand, the polishing step S50 grinds the front surface 11 of the nitride semiconductor layer 14 by means of CMP. After the protective film removal step S40, surface roughness is observed in the front surface 11 of the nitride semiconductor layer 14. The surface roughness has unevenness of at least approximately several nanometers resulting from the dissociation of nitrogen atoms (N). FIG. 6 schematically shows the region in which the surface roughness is observed as a damaged layer 19.

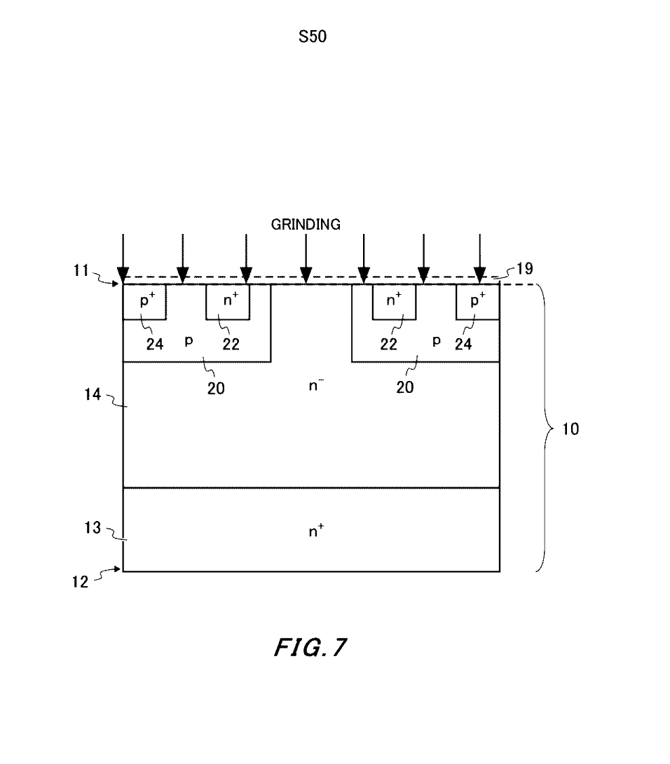

FIG. 7 shows the step S50 of polishing the front surface 11. The polishing step S50 is designed to remove the damaged layer 19 by polishing the front surface 11 of the nitride semiconductor layer 14. The polishing step S50 may use a single technique selected from CMP, dry etching, wet etching and chemical polishing using a catalyst. In the present exemplary embodiment, the polishing step S50 removes the nitride semiconductor layer 14 by a thickness of at least 10 nm or more, at most 200 nm.

Since the polishing step S50 is designed to remove a thickness of at least 10 nm or more, the polishing step S50 can remove the surface roughness of the front surface 11 with the removed thickness being minimized. In addition, the polishing step S50 can accomplish the goal of removing the surface roughness simply by removing, at most, a thickness of 200 nm. In the present exemplary embodiment, CMP is employed to grind a thickness of 50 nm from the front surface 11. In the present specification, the surface of the nitride semiconductor layer 14, which is obtained on completion of the polishing step S50, that faces away from the junction surface at which the high-concentration impurity layer 13 and the nitride semiconductor layer 14 are connected to each other will be referred to as a new front surface 11. In the case of chemical polishing using a catalyst, quartz, which serves as a solid catalyst, is brought into contact with the front surface 11 of the nitride semiconductor layer 14, which is the target to be polished, in a neutral phosphoric acid buffer solution, for example. In this manner, the front surface 11 of the nitride semiconductor layer 14 may be irradiated with ultraviolet rays through the quartz to grind the front surface 11. This technique can produce a more planar front surface 11 when compared with CMP, dry etching and wet etching.

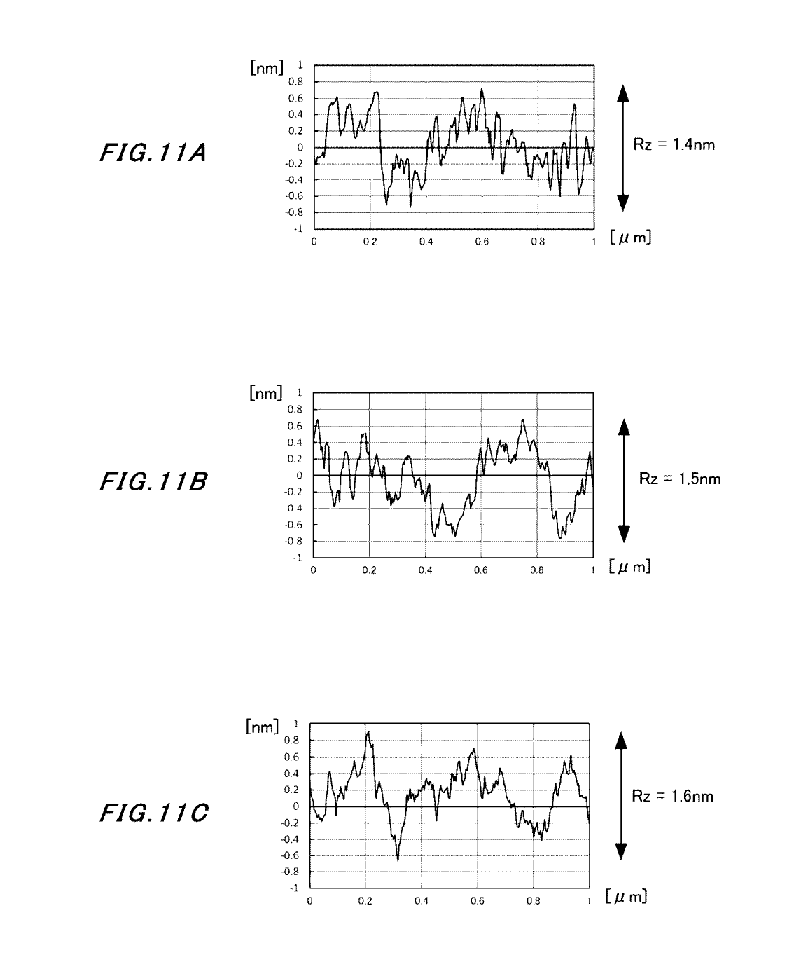

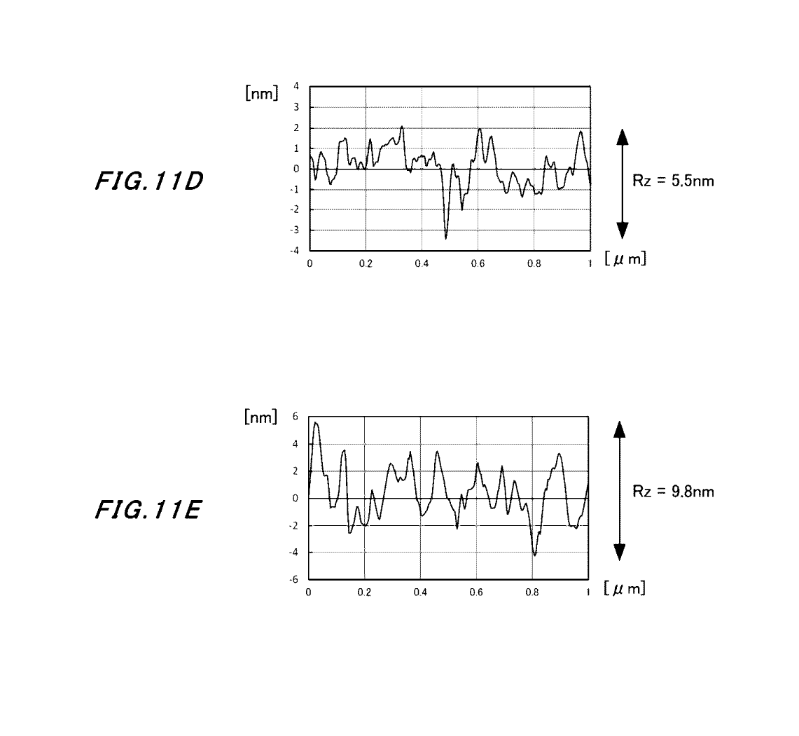

The thickness by which the nitride semiconductor layer 14 is removed by the polishing step S50 may be controlled depending on the temperature at which the thermal treatment is performed in the thermal treatment step S30. As the temperature of the thermal treatment rises, the unevenness of the front surface 11 increases. Accordingly, as the temperature of the thermal treatment rises, the thickness to be removed may be controlled to increase. In this manner, the surface roughness can be reliably removed when the thermal treatment temperature is relatively high and unnecessarily deep grinding can be prevented when the thermal treatment temperature is relatively low. In order to understand the relation between the thermal treatment temperature and the unevenness of the front surface 11, the description made later in reference to FIGS. 11A to 13 should be also referred to.

The thickness by which the nitride semiconductor layer 14 is removed in the polishing step S50 may be adjusted also depending on the pressure of the atmosphere gas 32 used in the thermal treatment step S30. As the pressure of the atmosphere gas 32 rises in the thermal treatment step S30, the likelihood of the dessociation of the nitrogen atoms (N) from the nitride semiconductor layer 14 decreases. Thus, the thickness to be removed may be reduced as the pressure of the atmosphere gas 32 rises. In this manner, unnecessarily deep grinding can be prevented when the pressure of the atmosphere gas 32 is relatively high, and the surface roughness can be reliably removed when the pressure of the atmosphere gas 32 is relatively low.

After the completion of the polishing step S50, the maximum height roughness Rz of the front surface 11 of the nitride semiconductor layer 14 is less than 1 nm in the present exemplary embodiment. Generally, the term “the maximum height roughness Rz” is defined in relation to the graph showing a part of the contour curve representing the unevenness, where the part corresponds to a sampling length L defined in the direction in which the average line of the contour curve extends. In this graph, the term “the maximum height roughness Rz” means the difference between the height Rp of the highest peak measured from the average line and the depth Rv of the deepest valley measured from the average line. In the present specification, the phrase “the front surface 11 is flat” is defined as meaning that the maximum height roughness Rz of the front surface 11 of the nitride semiconductor layer 14 is less than 1 nm.

FIG. 8 shows the step S60 of forming a front-surface structure 40 and a back-surface structure 50. In the present exemplary embodiment, the front-surface structure 40 includes a gate electrode 42, a gate insulator 44, and a source electrode 46, and the back-surface structure 50 includes a drain electrode 52. However, the front-surface structure 40 and the back-surface structure 50 are not limited to such and may include other structures.

The gate insulator 44 is in contact with the n⁻-type nitride semiconductor layer 14 externally exposed on the front surface 11. In the present exemplary embodiment, the gate insulator 44 is a silicon dioxide (SiO₂) film, but may be an aluminum oxide (Al₂O₃) film. Furthermore, the gate electrode 42 is in contact with the gate insulator 44. In the present exemplary embodiment, the gate electrode 42 includes a nickel (Ni) layer and a gold (Au) layer stacked on and in contact with the Ni layer, but may be a polycrystalline silicon (poly-Si) layer.

The source electrode 46 is at least in contact with the n⁺-type source region 22 and the p⁺-type contact region 24. The source electrode 46 may be provided in such a manner as to sandwich or surround the gate insulator 44 within the plane of the front surface 11. The drain electrode 52 is in contact with the back surface 12 of the high-concentration impurity layer 13. In the present exemplary embodiment, the source electrode 46 and the drain electrode 52 both include a titanium (Ti) layer and an Al layer stacked on and in contact with the Ti layer. In the present exemplary embodiment, the front-surface structure 40 is a so-called planar structure but may be instead a trench structure, where the gate electrode 42 and the gate insulator 44 are shaped as trenches.

As a result of performing the steps S10 to S60, the nitride semiconductor device 100 is completed, which is a vertical transistor. In the present exemplary embodiment, the damaged layer 19 is removed to obtain a flat surface, which can resultantly reduce nitrogen vacancies. Accordingly, an appropriate p-type carrier concentration can be achieved in the p-type impurity regions in the nitride semiconductor layer 14, i.e., the base region 20, the contact region 24 and the like. In addition, since a flat surface can be obtained by removing the damaged layer 19, a layer contaminated by the protective film 18 can also be removed. As a result, the impurity concentration as designed can be achieved on the front surface 11 of the semiconductor device 100.

The protective film 18 may be peeled off when the thermal treatment step S30 is performed at a high temperature of approximately 1400° C. According to the present exemplary embodiment, the nitrogen vacancies can be still reduced since the damaged layer 19 is removed and a flat surface is obtained. This means that the manufacturing process can be highly flexibly designed independent from the temperature of the thermal treatment step S30. Note that the technical ideas of the present exemplary embodiment are not limited to vertical transistors and may be applied to diodes.

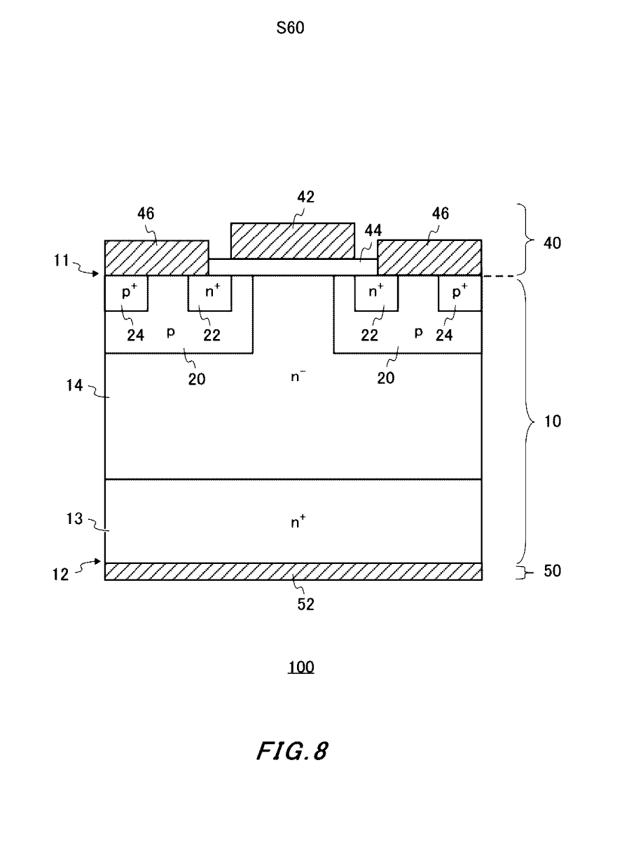

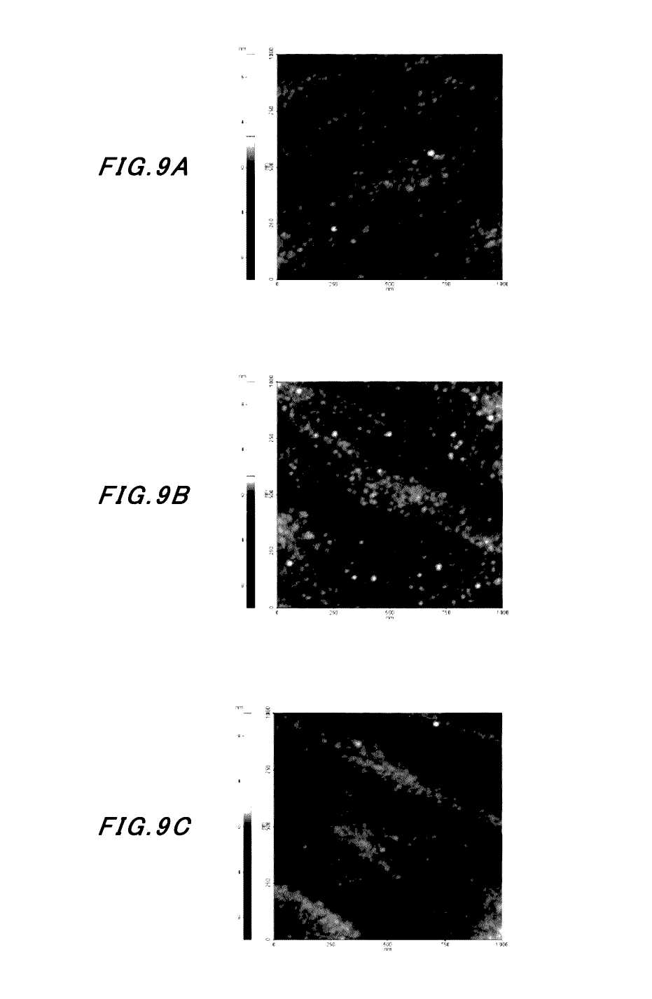

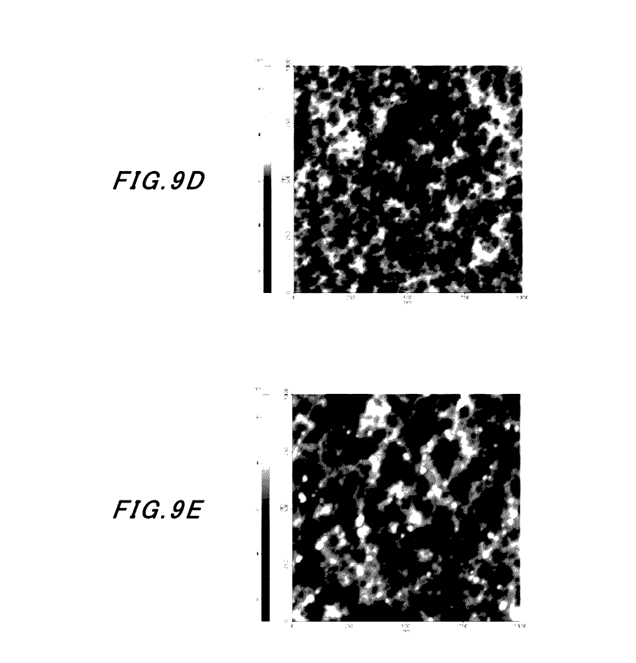

FIGS. 9A to 9E are AFM images showing the front surface 11 of the semiconductor substrate 10. The AFM images show the unevenness of the front surface 11 observed after the step S40 of removing the protective film 18 and before the step S50 of polishing the front surface 11. Stated differently, the AFM images show the unevenness of the damaged layer 19.

In the AFM images, the white color indicates that the portion is higher than a reference point or 0 nm, and the black color indicates that the portion is lower than the reference point or 0 nm and the gradations between the white color and the black color indicate how much higher or lower. FIGS. 9A to 9E correspond to different temperatures in the thermal treatment step S30, and FIG. 9A corresponds to 1100° C., FIG. 9B 1200° C., FIG. 9C 1300° C., FIG. 9D 1350° C., and FIG. 9E 1400° C. For all of the cases shown in FIGS. 9A to 9E, the duration of the thermal treatment is 5 minutes and the annealing furnace 30 is filled with the atmosphere gas 32 principally including nitrogen at 1 atm.

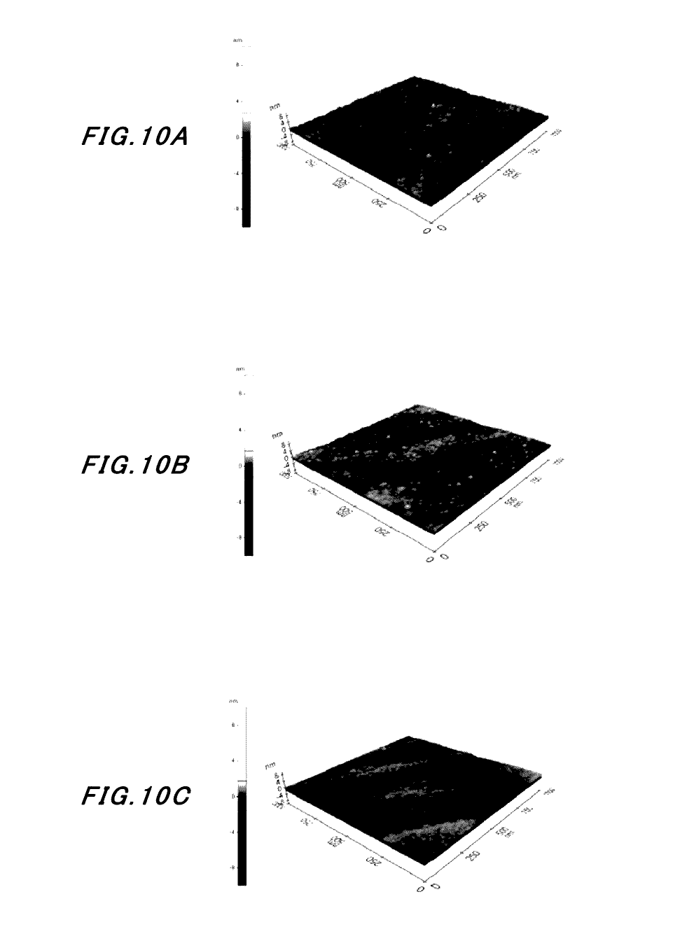

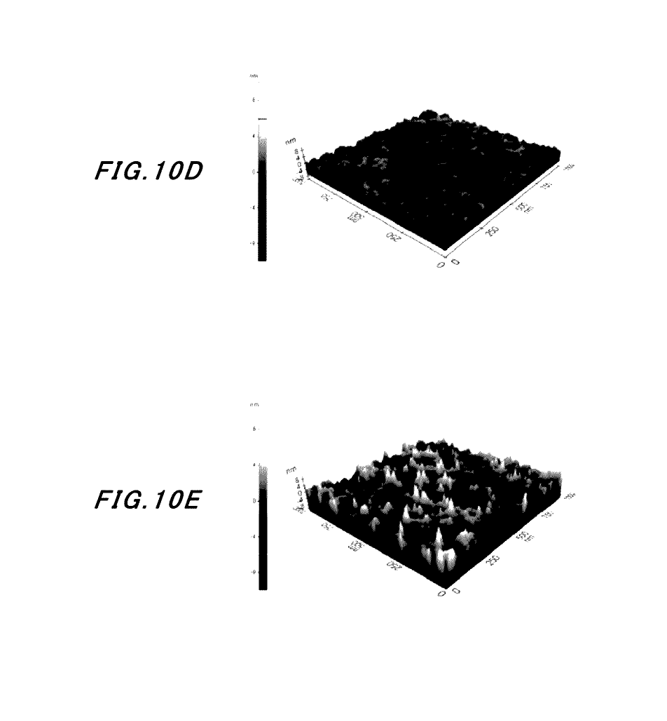

FIGS. 10A to 10E are three-dimensional views showing the unevenness of the front surface 11 of the semiconductor substrate 10. FIGS. 10A to 10E respectively correspond to FIGS. 9A to 9E. It can be generally seen from the drawings that, as the temperature rises, the unevenness of the front surface 11 increases.

FIGS. 11A to 11E are graphs showing the unevenness of the front surface 11 of the semiconductor substrate 10. FIGS. 11A to 11E respectively correspond to FIGS. 9A to 9E and FIGS. 10A to 10E. For example, the graph shown in FIG. 11A shows, in cross-section, the unevenness represented in FIG. 9A and FIG. 10A. The same correspondence is true to FIGS. 11B to 11E.

In FIGS. 11A to 11E, the sampling length L is 1.0 μm. In the present exemplary embodiment, the parameter Rz is calculated in the sampling length L. The parameter Rz is 1.4 nm for FIG. 11A, 1.5 nm for FIG. 11B, 1.6 nm for FIG. 11C, 5.5 nm for FIG. 11D, and 9.8 nm for FIG. 11E. FIGS. 11A to 11E confirm that the parameter Rz tends to increase as the temperature of the thermal treatment rises.

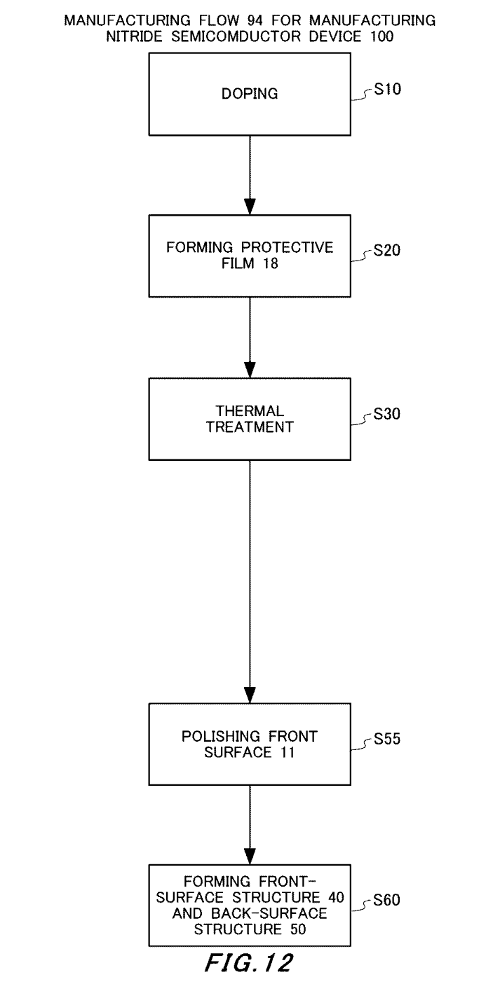

FIG. 12 shows a manufacturing flow 94 for manufacturing the nitride semiconductor device 100 according to a second embodiment. In the present exemplary embodiment, a step S55 of polishing the front surface 11 is performed in place of the removal step S40 and the polishing step S50 of the first embodiment. In the present exemplary embodiment, the removal step S40 and the polishing step S50, which are separately performed on the front surface 11 in the first embodiment, are continuously performed using the same single technique. Since the removal step S40 and the polishing step S50 can be completed without changing the technique in the present exemplary embodiment, a simpler manufacturing process is possible when compared with the first embodiment. In this resect, the second embodiment is different from the first embodiment.

Except for this, the second embodiment is the same as the first embodiment. Note that the present exemplary embodiment only requires that the same single technique be used and the conditions under which the CMP or etching is performed may be thus modified as appropriate.

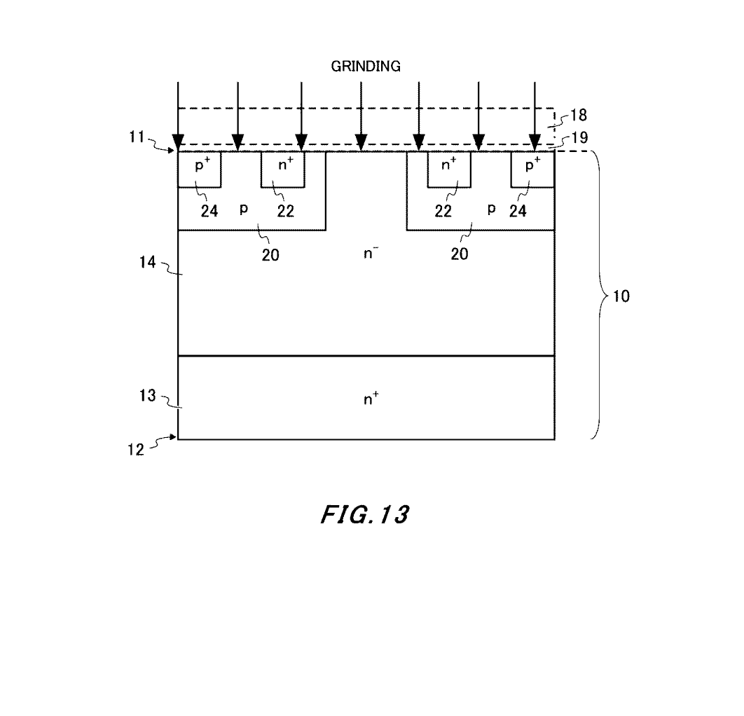

FIG. 13 shows the step S55 of polishing the front surface 11. As described above, the protective film 18 and the damaged layer 19 are removed by the step S55 of polishing the front surface 11 in the present exemplary embodiment. The present exemplary embodiment only requires a single set of apparatuses that can perform both the removal step S40 and the polishing step S50 and can thus manufacture the nitride semiconductor device 100 at a lower cost than the first embodiment.

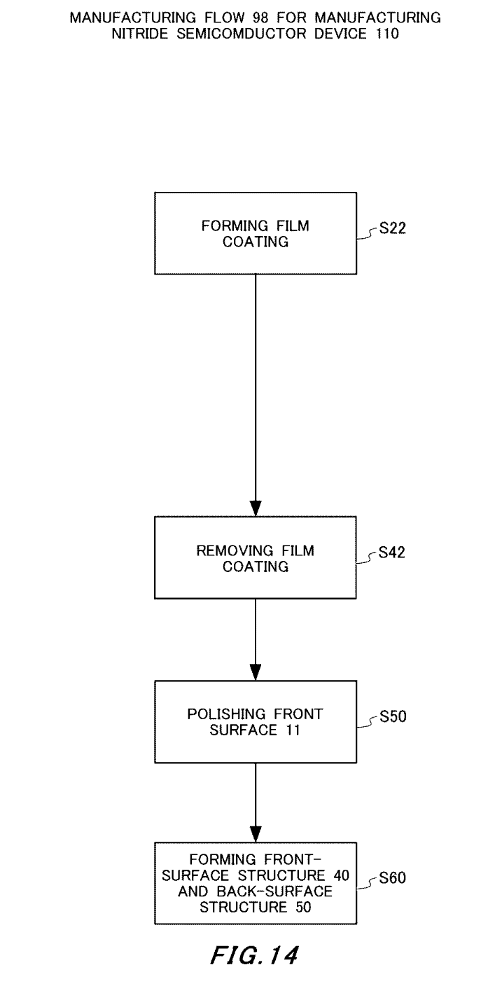

FIG. 14 shows a manufacturing flow 98 for manufacturing a nitride semiconductor device 110 according to a third embodiment. The present exemplary embodiment does not perform the doping step S 10 and the thermal treatment step S30. According to the present exemplary embodiment, the unevenness of the front surface 11 is caused by a step S22 of forming a film coating on the front surface 11 of the nitride semiconductor layer 14 and a step S42 of removing this film coating. The step S50 of polishing the front surface 11 is performed to remove such unevenness. In this resect, the third embodiment is different from the first embodiment. Except for this, the third embodiment is the same as the first embodiment.

For example, the film coating may be formed on the front surface 11 using sputtering, according to which atoms, molecules or ions are physically ejected from a target and adhere to the front surface 11. This approach is likely to cause unevenness in the front surface 11. In addition, unevenness is also likely to be caused in the front surface 11 when plasma CVD, which is a type of CVD, is employed to form the film coating on the front surface 11. In addition, if CMP, dry etching or wet etching is employed to remove the protective film 18, the front surface 11 may be polished but a general part of the unevenness that has been caused in the front surface is still left. To address this issue, the third embodiment may include a step of polishing the front surface 11 after the film coating is formed and removed. In this way, the front surface 11 can be made planar.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### DESCRIPTION OF REFERENCE NUMERALS

10 . . . semiconductor substrate, 11 . . . front surface, 12 . . . back surface, 13 . . . high-concentration impurity layer, 14 . . . nitride semiconductor layer, 18 . . . protective film, 19 . . . damaged layer, 20 . . . base region, 22 . . . source region, 24 . . . contact region, 30 . . . annealing furnace, 32 . . . atmosphere gas, 40 . . . front-surface structure, 42 . . . gate electrode, 44 . . . gate insulator, 46 . . . source electrode, 50 . . . back-surface structure, 52 . . . drain electrode, 90 . . . manufacturing flow, 94 . . . manufacturing flow, 98 . . . manufacturing flow, 100 . . . nitride semiconductor device, 110 . . . nitride semiconductor device

What is claimed is:

1. A method of manufacturing a nitride semiconductor device, comprising:
thermally treating a nitride semiconductor layer or removing a film formed on a front surface of the nitride semiconductor layer; and
polishing the front surface of the nitride semiconductor layer after the thermally treating or the removing.

2. The method of manufacturing a nitride semiconductor device as set forth in claim 1, wherein
the thermally treating includes thermally treating the nitride semiconductor layer at a highest temperature from among a plurality of treatments performed to manufacture the nitride semiconductor device.

3. The method of manufacturing a nitride semiconductor device as set forth in claim 2, further comprising
prior to the thermally treating, doping the front surface of the nitride semiconductor layer with impurities.

4. The method of manufacturing a nitride semiconductor device as set forth in claim 3, further comprising
subsequent to the doping and prior to the thermally treating, forming a protective film on the front surface of the nitride semiconductor layer, wherein
the protective film is one of an aluminum nitride film, a silicon nitride film and a silicon oxide film.

5. The method of manufacturing a nitride semiconductor device as set forth in claim 3, wherein
the impurities are:
at least one element selected from among magnesium, beryllium and zinc when the impurities are p-type impurities for the nitride semiconductor layer; and
silicon or germanium when the impurities are n-type impurities for the nitride semiconductor layer.

6. The method of manufacturing a nitride semiconductor device as set forth in claim 3, wherein
the impurities are p-type impurities for the nitride semiconductor layer.

7. The method of manufacturing a nitride semiconductor device as set forth in claim 1, wherein
the polishing uses a single technique selected from among CMP, dry etching, wet etching and chemical polishing using a catalyst.

8. The method of manufacturing a nitride semiconductor device as set forth in claim 4, further comprising
subsequent to the thermally treating and prior to the polishing, removing the protective film using a single technique selected from among CMP, dry etching and wet etching, wherein
the polishing and the removing the protective film are continuously performed using the same single technique.

9. The method of manufacturing a nitride semiconductor device as set forth in claim 4, further comprising
subsequent to the thermally treating and prior to the polishing, removing the protective film using a single technique selected from among CMP, dry etching and wet etching, wherein
the polishing and the removing the protective film are performed using different techniques.

10. The method of manufacturing a nitride semiconductor device as set forth in claim 1, wherein
the polishing removes the nitride semiconductor layer by a thickness of at least 10 nm.

11. The method of manufacturing a nitride semiconductor device as set forth in claim 1, wherein
the polishing removes the nitride semiconductor layer by a thickness of at most 200 nm.

12. The method of manufacturing a nitride semiconductor device as set forth in claim 1, wherein
the thickness by which the nitride semiconductor layer is removed in the polishing is adjusted depending on a temperature at which the thermally treating is performed.

13. The method of manufacturing a nitride semiconductor device as set forth in claim 1, wherein
the thickness by which the nitride semiconductor layer is removed in the polishing is adjusted depending on a pressure of an atmosphere gas used in the thermally treating.

14. The method of manufacturing a nitride semiconductor device as set forth in claim 1, wherein
after the polishing, maximum height roughness Rz of the front surface of the nitride semiconductor layer is less than 1 nm.

15. A nitride semiconductor device comprising:
a nitride semiconductor layer; and
an impurity region provided in the nitride semiconductor layer on a side of a front surface thereof, wherein
maximum height roughness Rz of the front surface of the nitride semiconductor layer is less than 1 nm.

16. The nitride semiconductor device as set forth in claim 15, wherein
impurities in the impurity region are p-type impurities for the nitride semiconductor layer.
